(19) United States
(12) Patent Application Publication
(10) Pub. No.: US 2009/0072218 A1
(43) Pub. Date: Mar. 19, 2009

(54) Higher threshold voltage phase change memory

(76) Inventors: Semyon Savransky, Newark, CA (US); Ilya Karpov, Santa Clara, CA (US); Jason Reid, San Jose, CA (US)

Correspondence Address: TROP, PRUNER & HU, P.C., 1616 S. VOSS ROAD, SUITE 750, HOUSTON, TX, 77057-2631, US

(21) Appl. No.: 11/901,492

(22) Filed: Sep. 18, 2007

(51) Int. Cl. H01L 47/00

(52) U.S. Cl. 257/4; 257/E47.001

(57) ABSTRACT

A phase change memory may be formed of a phase change material alloy that produces a higher threshold voltage and, in some cases, is operable at higher temperatures. For example, the formulation may include a poor metal, antimony, and at least one of tellurium or selenium.

### BACKGROUND

This relates generally to phase change memories using chalcogenide alloys.

Phase change memory devices use phase change materials, i.e., materials that may be electrically switched between a generally amorphous and a generally crystalline state, for electronic memory application. One type of memory element utilizes a phase change material that may be, in one application, electrically switched between a structural state of generally amorphous and generally crystalline local order or between different detectable states of local order across the entire spectrum between completely amorphous and completely crystalline states. The state of the phase change materials is also non-volatile in that, when set in either a crystalline, semi-crystalline, amorphous, or semi-amorphous state representing a resistance value, that value is retained until changed by another programming event, as that value represents a phase or physical state of the material (e.g., crystalline or amorphous). The state is unaffected by removing electrical power.

### BRIEF DESCRIPTION OF THE DRAWINGS

FIG. 1 is a schematic view of one embodiment of the present invention;

FIG. 2 is a cross-sectional view of the memory element of FIG. 1, in one embodiment; and

FIG. 3 is a system depiction for one embodiment of the present invention.

### DETAILED DESCRIPTION

Phase change memories commonly use so-called GST alloys including germanium, antimony, and tellurium. Those alloys have certain disadvantages, including the fact that their threshold voltage generally lies in the range of 0.9 to 1.4 volts. This limited threshold voltage range limits the read window for a cross point memory array using a phase change memory cell in combination with an ovonic threshold switch used as a selection device. The data retention energy for GST alloys is close to the acceptable limits for many applications, such as cell phone applications, but may not be acceptable for some other applications that require higher usage temperatures.

In order to increase the threshold voltage of the memory element, a phase change material alloy of the formulation A-Sb-Ch may be utilized. The component A, in the above described alloy, is a high atomic mass element taken from the periodic table below the connecting elements Al—Ge—Sb—Po in Groups III, IV, V, and VI. For example, the element A can be gallium, indium, thallium, bismuth, tin, or lead, or their combinations, including, for example, GaIn or TlBi. The component A includes what is sometimes called “poor metals.”

The component Ch may be tellurium or selenium or a mixture containing the two. In addition to the components A, Sb, and Ch, other elements can be included in the alloy.

As a non-limiting example, one exemplary composition may include gallium (1.5-2.5), antimony (1.5-2.5), and tellurium (4-6). Another suitable composition may include indium (1.5-2.5), antimony (1.5-2.5), and tellurium (4-6). Still another composition may include In₃SbTe₂.

In some embodiments, the alloy, without germanium, exhibits an increased threshold voltage due to the difficulty in creating crystal nuclei in the conducting filament through the amorphous part of the phase change material. The alloy may also show increased activation energy for data retention due to an increase in the energy of crystallization.

For example, the formulation may include indium, antimony, and tellurium with a crystallization energy of 2.9 eV, gallium, antimony, and tellurium with a crystallization energy of 2.8 eV, germanium, antimony, tellurium, and bismuth with a crystallization energy of 2.7 eV, or Pb₁₁Co₈₁In₅₈Se₂₃ with a crystallization energy of 2.9 eV. This is in comparison to GST alloys, such as Ge₂Sb₂Te₅, which generally have a crystallization energy of 2.35 eV. Thus, in some embodiments, the phase change material may have a crystallization energy greater than about 2.5 eV.

Crystallization energy is the energy needed to transform an amorphous solid into a crystalline solid. See C. Barrett, W. Nix, and A. Tetelman, The Principles of Engineering Materials (Prentice Hall 1973) at page 163. In phase change materials, crystallization energy may be determined by measuring the dependence of resistance on temperature and heating rate. Crystallization energy may be calculated with a Kissinger plot.

Advantageously, the alloy may have a threshold voltage of greater than 2 volts in some embodiments. In one embodiment, a memory element using the alloy may have a threshold voltage of about 2.2 volts.

In one embodiment of the present invention, the element A may make up about one atomic percent to 75 atomic percent of the phase change material, the element Ch may make up from about 0.001 to 65 atomic percent, and the element Sb may make up from 0.001 to 65 atomic percent of the material.

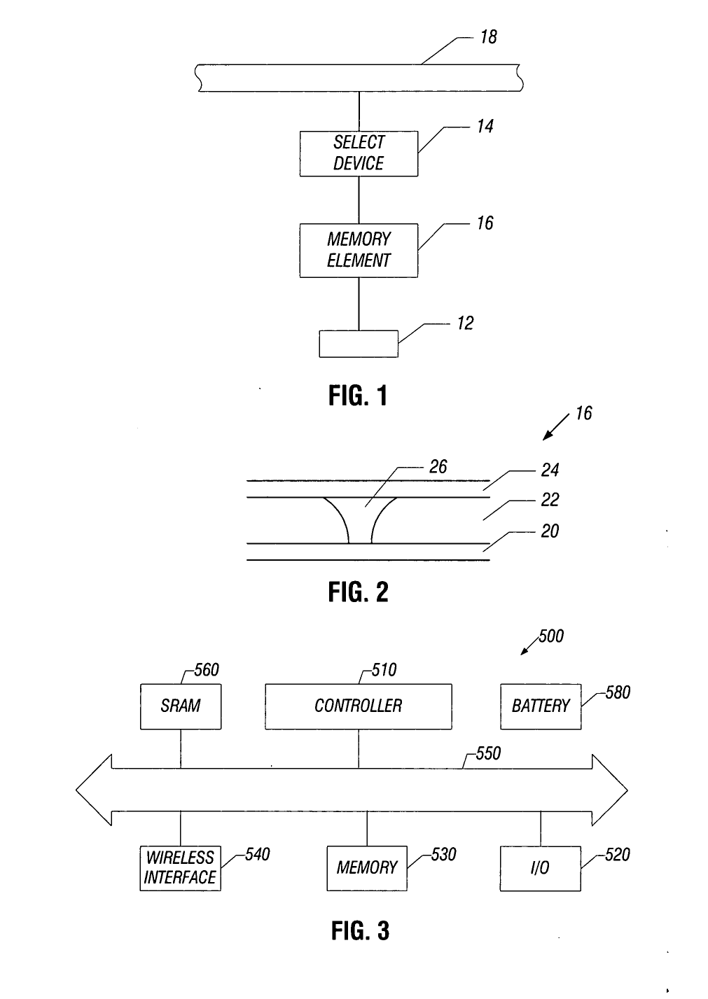

Referring to FIG. 1, a series connected select device 14 may be used to access a memory element 16, including a phase change material, during programming or reading of memory element. Address lines 12 and 18 may be used to access individual memory elements 16 in an array of phase change memory cells. A select device 14 may be an ovonic threshold switch that can be made of a chalcogenide alloy that does not exhibit an amorphous to crystalline phase change and which undergoes rapid, electric field initiated change in electrical conductivity that persists only so long as a holding voltage is present. The select device may also be a transistor, diode, or other device that is capable of regulating the current that passes through memory element 16.

Referring to FIG. 2, in accordance with one embodiment, a phase change memory element 16 for a non-volatile memory may include a semiconductor substrate, over which is formed a conducting lower electrode 20 and a conducting upper electrode 24. Between the electrodes 20 and 24 may be a dielectric material 22 with a pore filled with a phase change formulation 26 described herein. While one structure is shown, the present invention is not limited to any particular structure for the memory cell.

A select device may operate as a switch that is either “off” or “on” depending on the amount of voltage potential applied between address lines 12 and 18 and more particularly whether the current through the select device exceeds its threshold current or voltage, which then triggers the device into the on state. The off state may be a substantially electrically nonconductive state and the on state may be a substantially conductive state, with less resistance than the off state.

In the on state, the voltage across an ovonic threshold switch select device is equal to its holding voltage V_{H} plus IxRon, where Ron is the dynamic resistance from the extrapolated X-axis intercept, V_{H}. For example, a select device may have threshold voltages and, if a voltage potential less than the threshold voltage of a select device is applied across the select device, then the select device may remain “off” or in a relatively high resistive state so that little or no electrical current passes through the memory cell and most of the voltage drop from selected row to selected column is across the select device. Alternatively, if a voltage potential greater than the threshold voltage of a select device is applied across the select device, then the select device may “turn on,” i.e., operate in a relatively low resistive state so that electrical current passes through the memory cell. In other words, one or more series connected select devices may be in a substantially electrically nonconductive state if less than a predetermined voltage potential, e.g., the threshold voltage, is applied across select devices. Select devices may be in a substantially conductive state if greater than the predetermined voltage potential is applied across select devices. Select devices may also be referred to as an access device, an isolation device, or a switch.

In one embodiment, each select device may comprise a switching material such as, for example, a chalcogenide alloy, and may be referred to as an ovonic threshold switch, or simply an ovonic switch. The switching material of select devices may be a material in a substantially amorphous state positioned between two electrodes that may be repeatedly and reversibly switched between a higher resistance “off” state (e.g., greater than about ten megaOhms) and a relatively lower resistance “on” state (e.g., about one thousand Ohms in series with V_{H}) by application of a predetermined electrical current or voltage potential. In this embodiment, each select device may be a two terminal device that may have a current-voltage (I-V) characteristic similar to a phase change memory element that is in the amorphous state. However, unlike a phase change memory element, the switching material of select devices may not change phase. That is, the switching material of select devices may not be a programmable material, and, as a result, select devices may not be a memory device capable of storing information. For example, the switching material of select devices may remain permanently amorphous and the I-V characteristic may remain the same throughout the operating life.

In the low voltage or low electric field mode, i.e., where the voltage applied across select device is less than a threshold voltage (labeled V_{TH}), a select device may be “off” or nonconducting, and exhibit a relatively high resistance, e.g., greater than about 10 megaohms. The select device may remain in the off state until a sufficient voltage, e.g., V_{TH}, is applied, or a sufficient current is applied, e.g., I_{TH}, that may switch the select device to a conductive, relatively low resistance on state. After a voltage potential of greater than about V_{TH} is applied across the select device, the voltage potential across the select device may drop (“snapback”) to a holding voltage potential, V_{H}. Snapback may refer to the voltage difference between V_{TH} and V_{H} of a select device.

In the on state, the voltage potential across select device may remain close to the holding voltage of V_{H} as current passing through select device is increased. The select device may remain on until the current through the select device drops below a holding current, I_{H}. Below this value, the select device may turn off and return to a relatively high resistance, nonconductive off state until the V_{TH} and I_{TH} are exceeded again.

In some embodiments, only one select device may be used. In other embodiments, more than two select devices may be used. A single select device may have a V_{H} about equal to its threshold voltage, V_{TH}, (a voltage difference less than the threshold voltage of the memory element) to avoid triggering a reset bit when the select device triggers from a threshold voltage to a lower holding voltage called the snapback voltage. In another example, the threshold current of the memory element may be about equal to the threshold current of the access device even though its snapback voltage is greater than the memory element's reset bit threshold voltage.

Programming of the chalcogenide to alter the state or phase of the material may be accomplished by applying voltage potentials to the lower electrode 20 and upper electrode 24, thereby generating a voltage potential across the select device and memory element. When the voltage potential is greater than the threshold voltages of select device 14 and memory element 16, then an electrical current may flow through the chalcogenide in response to the applied voltage potentials, and may result in heating of the chalcogenide.

This heating may alter the memory state or phase of the chalcogenide. Altering the phase or state of the chalcogenide may alter the electrical characteristic of memory material, e.g., the resistance of the material may be altered by altering the phase of the memory material. Memory material may also be referred to as a programmable resistive material.

In the “reset” state, memory material may be in an amorphous or semi-amorphous state and in the “set” state, memory material may be in an a crystalline or semi-crystalline state. The resistance of memory material in the amorphous or semi-amorphous state may be greater than the resistance of memory material in the crystalline or semi-crystalline state. It is to be appreciated that the association of reset and set with amorphous and crystalline states, respectively, is a convention and that at least an opposite convention may be adopted.

Using electrical current, memory material may be heated to a relatively higher temperature to amorphize memory material and “reset” memory material (e.g., program memory material to a logic “0” value). Heating the volume of memory material to a relatively lower crystallization temperature may crystallize memory material and “set” memory material (e.g., program memory material to a logic “1” value). Various resistances of memory material may be achieved to store information by varying the amount of current flow and duration through the volume of memory material.

Turning to FIG. 3, a portion of a system 500 in accordance with an embodiment of the present invention is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, a cellular network, although the scope of the present invention is not limited in this respect.

System 500 may include a controller 510, an input/output (I/O) device 520 (e.g. a keypad, display), static random access memory (SRAM) 560, a memory 530, and a wireless interface 540 coupled to each other via a bus 550. A battery 580 may be used in some embodiments. It should be noted that the scope of the present invention is not limited to embodiments having any or all of these components.

Controller 510 may comprise, for example, one or more microprocessors, digital signal processors, microcontrollers, or the like. Memory 530 may be used to store messages transmitted to or by system 500. Memory 530 may also optionally be used to store instructions that are executed by controller 510 during the operation of system 500, and may be used to store user data. Memory 530 may be provided by one or more different types of memory. For example, memory 530 may comprise any type of random access memory, a volatile memory, a non-volatile memory such as a flash memory and/or a memory such as memory discussed herein.

I/O device 520 may be used by a user to generate a message. System 500 may use wireless interface 540 to transmit and receive messages to and from a wireless communication network with a radio frequency (RF) signal. Examples of wireless interface 540 may include an antenna or a wireless transceiver, although the scope of the present invention is not limited in this respect.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. a semiconductor phase change memory comprising:
a pair of electrodes; and
a phase change memory material between said electrodes, said memory material including a poor metal, antimony, and at least one of tellurium or selenium.

2. The memory of claim 1 wherein atomic percentage of said poor metal in said phase change memory material is between 1% and 75%.

3. The memory of claim 2 wherein the atomic percentage of antimony in said phase change memory material is less than 65%.

4. The memory of claim 3 wherein the combined atomic percentage of tellurium and selenium in said phase change memory material is less than 65%.

5. The memory of claim 1 wherein said poor metal is thallium, bismuth, tin, or lead.

6. The memory of claim 1 wherein said phase change memory material includes two or more poor metals.

7. The memory of claim 1 wherein said phase change memory material has a crystallization energy greater than about 2.5 eV.

8. The memory of claim 1 wherein said phase change memory material has a crystallization energy greater than the crystallization energy of Ge₂Sb₂Te₅.

9. The memory of claim 1 wherein said memory has a threshold voltage of greater than about 2 volts.

10. The memory of claim 1 wherein said memory has a threshold voltage of greater than the threshold voltage of Ge₂Sb₂Te₅.

11. The memory of claim 1 further including an ovonic threshold switch in series with said phase change memory material.

12. The memory of claim 1 wherein said phase change memory material is free of germanium.

13. A semiconductor phase change memory comprising:
a pair of electrodes; and
a phase change memory material having a crystallization energy greater than about 2.5 eV.

14. The memory of claim 13 wherein said memory has a threshold voltage greater than about 2 volts.

15. The memory of claim 13 including an ovonic threshold switch in series with said phase change memory material.

16. The memory of claim 13 wherein said memory material is free of germanium.

17. A system comprising:
a processor;
a wireless interface coupled to said processor; and
the phase change memory of claim 1 coupled to said wireless interface.

18. The system of claim 17 wherein said phase change memory includes a material having a crystallization energy greater than about 2.5 eV.

19. The system of claim 17 including a memory having a threshold voltage greater than about 2 volts.
